(19) United States
(12) Patent Application Publication
(10) Pub. No.: US 2008/0156369 A1
(43) Pub. Date: Jul. 3, 2008

(54) Active layers utilized in solar cells and fabrication method thereof

(75) Inventors: Bao-Tsan Ko, Pingtung County (TW); Shu-Hua Chan, Miaoli (TW); Ching Ting, Hsinchu (TW); Yi-Chun Chen, Hsinchu City (TW); Hsiang-Jui Chen, Hsinchu City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/785,231

(22) Filed: Apr. 16, 2007

(30) Foreign Application Priority Data
Dec. 29, 2006 (TW) 95149924

(51) Int. Cl. H01L 31/00; B05D 5/12

(52) U.S. Cl. 136/258; 427/74

(57) ABSTRACT

An active layer utilized in a solar cell. The active layer includes a polymer film having a plurality of hollow column array structures formed therein and a semiconductor material filled in the hollow column structures. The invention also provides a method of fabricating the active layer utilized in a solar cell.

### BACKGROUND OF THE INVENTION

1. Field of the Invention

The invention relates to a semiconductor layer, and in particular to an active layer utilized in solar cells and fabrication method thereof.

2. Description of the Related Art

Organic polymer solar cells are mainly fabricated in solution processes. After absorption of solar energy, electron/hole separation is generated from P/N material blending. Electrons and holes are then respectively transmitted to anode and cathode through conducting material to produce potential drop, finally producing electrical energy. Currently, bulk heterojunction (BHJ) is widely utilized in organic hybrid solar optoelectronics. Conducting polymers are blended with nanocrystals or fullrene derivative materials to form a light-absorbing conducting active layer. Indium Tin Oxide (ITO) substrate and electrodes are then assembled to form a solar cell. The mechanism of solar optoelectronic conversion system includes four critical steps.

The first step is light absorption. After light absorption, electrons are excited from HOMO state to LUMO state. Electron/hole pairs (excitons) are thus produced. The second step is exciton diffusion. The excitons are moved in the same medium. Generally, the diffusion distance is about 10 nm. The third step is charge separation. The excitons are separated into independent electrons and holes. Charge separation often occurs at heterojunction due to negative electricity variations, almost 90% for organic blending devices. The final step is charge collection. Electrons and holes are effectively transferred to corresponding electrodes to produce electric current to drive the device.

The total efficiency of the four steps constitutes final cell efficiency. Thus, controls of nano-morphology and interface of the P/N material are critical factors affecting charge separation and transmission.

### BRIEF SUMMARY OF THE INVENTION

The invention provides an active layer utilized in a solar cell comprising a polymer film having a plurality of hollow column array structures formed therein and a semiconductor material filled in the hollow column structures.

The invention also provides a method of fabricating an active layer utilized in a solar cell comprising self-assembling a plurality of block copolymers to form a polymer film on a substrate, removing a portion of the block copolymers to expose a plurality of hollow column array structures, and filling a semiconductor material in the hollow column structures.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a diagram of a fabrication method of an active layer utilized in a solar cell of the invention.

FIG. 2 is a polarized optical microscopy (POM) photograph of a block copolymer self-assembling structure of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides an active layer-utilized in a solar cell comprising a polymer film having a plurality of hollow column array structures formed therein and a semiconductor material filled in the hollow column structures.

The hollow column array structures are formed in the polymer film served as active layer, with a diameter of about 1˜100 nm. The polymer film may comprise poly(3-alkylthiophene), poly(p-phenylenevinylene), or polyfluorene, preferably poly(3-hexylthiophene) (P3HT). The hollow column structures are perpendicular to the polymer film surface.

The semiconductor material has a weight ratio of about 40˜80% and may be N-type and comprise light-absorbing semiconductor materials, carbonaceous materials, or combinations thereof. The light-absorbing semiconductor material may comprise CdS, CdSe, or CdTe. The carbonaceous material may comprise carbon 60 derivatives such as [6,6]-Phenyl-C₆₁ butyric acid methyl ester (PC₆₁MB) or carbon 70 derivatives such as [6,6]-Phenyl-C₇, butyric acid methyl ester (PC₇₁MB).

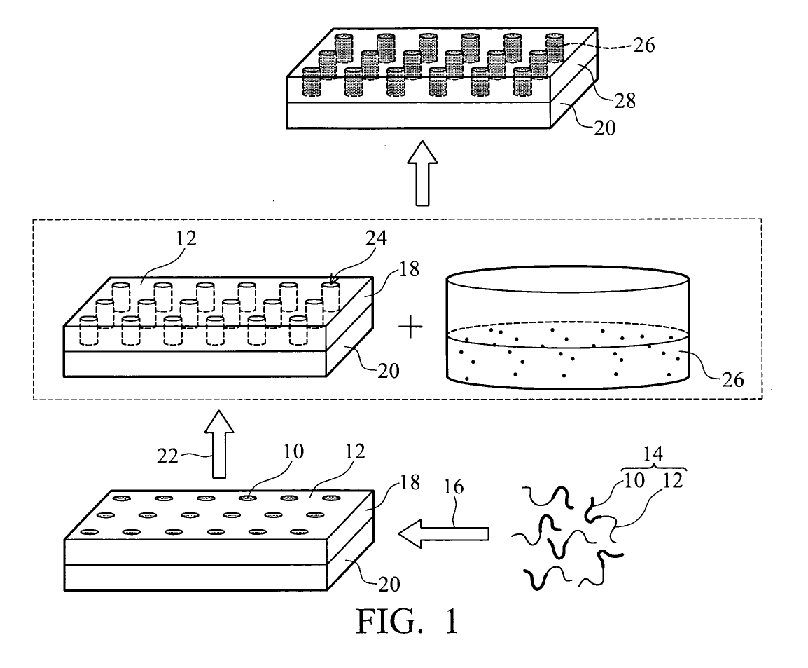

A method of fabricating an active layer utilized in a solar cell of the invention is disclosed in FIG. 1. A plurality of block copolymers 14 comprising a first copolymer 10 and a second copolymer 12 are self-assembled 16 to form a polymer film 18 on a substrate 20. Next, the first copolymers 10 are removed by decomposition 22 to expose a plurality of hollow column array structures 24. A semiconductor material 26 is then filled in the hollow column structures 24 to prepare a polymer film template 28 served as an active layer of solar cells.

The block copolymer may comprise conductive polymers and have a polydispersity index (PDI) less than 1.6. The first copolymer may comprise L-polylactic acid, meso-polylactic acid, polylactic acid, or polycaprolactone. The second copolymer may comprise poly(3-alkylthiophene), poly(p-phenylenevinylene), or polyfluorene. The first copolymer and the second copolymer are immiscible. Polylactic acid (PLA) and poly(3-hexylthiophene) (P3HT) are combined to form a chiral PLA-b-P3HT-b-PLA block copolymer. L-polylactic acid (PLLA) and poly(3-hexylthiophene) (P3HT) are combined to form a chiral PLLA-P3HT block copolymer.

The polymer film can be formed on the substrate such as slides, carbon-coated slides, Indium Tin Oxide (ITO) glass, silicon wafers, silicon oxide, inorganic light emitting diodes, or alumina by such as spin coating.

The film formed by block copolymer self-assembly is removed on portion selectively to prepare a nanopatterned template. When the polymer template is mixed with N-type materials to serve as an active layer of organic polymer solar cells, charge separation and transport are improved due to its high specific surface area and regular nano-morphology control.

### Preparation of PLA-b-P3HT-PLA

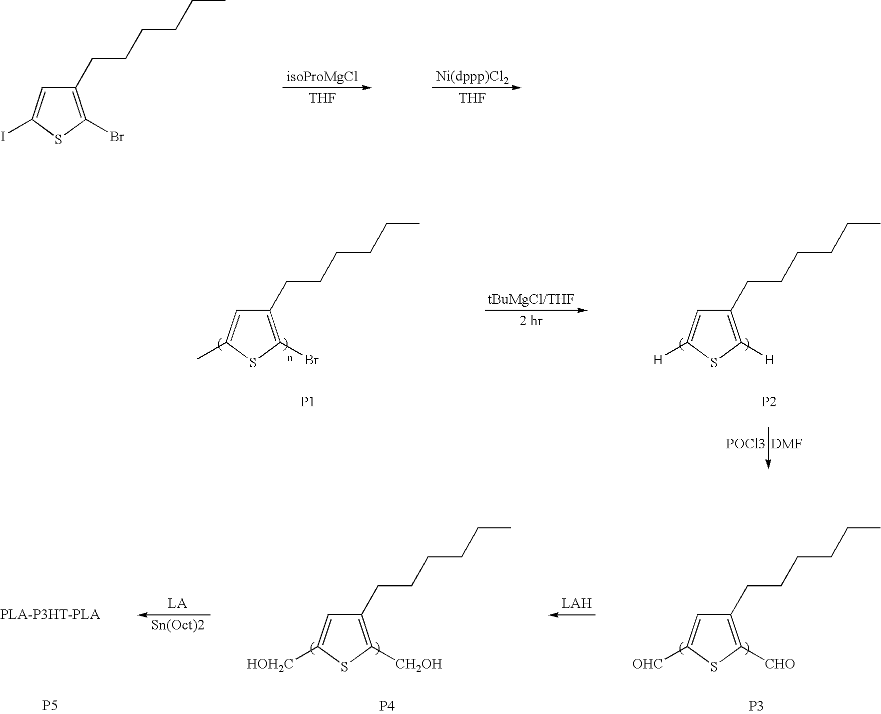

### EXAMPLE 1

### Preparation of poly(3-hexylthiophene) (P3HT) (P1)

3-bromothiophene (1 e.q.) was added to 0° C. dry tetrahydrofuran (THF) and stirred for 10 min under nitrogen. Next, isopropyl magnesium chloride (1.1 e.q.) was added at 0° C. and reacted for 2 hours. After returning to room temperature, Ni(dppp)Cl₂(0.02 e.q.), a catalyst, was added and reacted for 1 hour. After precipitation by adding methanol, the results were washed with abundant methanol to prepare poly(3-hexylthiophene) (P3HT) (P1) with 17,208 g/mol.

### EXAMPLE 2

### Preparation of poly(3-hexylthiophene) (P3HT) with H/H End Groups (P2)

0.3 g poly(3-hexylthiophene) (P3HT) (P1) (0.04 mmol) was dissolved in 80 mL dry tetrahydrofuran (THF). Next, 5 mL t-butyl magnesium chloride (2M in THF) was added and reacted at 80° C. for 2 hours. After cooling to room temperature, 3 mL hydrochloric acid (2M) was added to terminate the reaction. After precipitation by adding abundant methanol, the results were purified by soxhlet extraction to prepare poly(3-hexylthiophene) (P3HT) with H/H end groups (P2).

### EXAMPLE 3

### Preparation of poly(3-hexylthiophene) (P3HT) with CHO/CHO End Groups (P3)

0.3 g poly(3-hexylthiophene) (P3HT) with H/H end groups (P2) (0.04 mmol) was dissolved in 80 mL dry toluene. Next, 2 mL methyl formanilide (1N, 0.016 mol) and 1.3 mL phosphorus oxychloride (POCl₃) (0.014 mol) were added and reacted at 80° C. for 24 hours. After cooling to room temperature, sodium acetate aqueous solution was added to terminate the reaction. After precipitation by adding abundant methanol, the results were purified by soxhlet extraction to prepare poly(3-hexylthiophene) (P3HT) with CHO/CHO end groups (P3).

### EXAMPLE 4

### Preparation of poly(3-hexylthiophene) (P3HT) with OH/OH End Groups (P4)

0.3 g poly(3-hexylthiophene) (P3HT) with CHO/CHO end groups (P3) (0.04 mmol) was dissolved in 80 mL dry tetrahydrofuran (THF). Next, 1 mL lithium aluminum hydride (LiAlH₄) solution (1M) was added and reacted at room temperature for 40 min. 1 mL hydrochloric acid (1M) was then added to terminate the reaction. After precipitation by adding abundant methanol, the results were purified by soxhlet extraction to prepare poly(3-hexylthiophene) (P3HT) with OH/OH end groups (P4).

### EXAMPLE 5

### Preparation of PLA-b-P3HT-b-PLA (P5)

0.1 g poly(3-hexylthiophene) (P3HT) with OH/OH end groups (P4) was dissolved in 1 mL dry toluene. Next, 0.002 g Sn(Oct)₂ and 0.2 g lactide were added and reacted at 110° C. for 24 hours. After cooling to room temperature, abundant methanol was added to precipitate. The results were then purified by soxhlet extraction to prepare PLA-b-P3HT-PLA (P5).

### EXAMPLE 6

### Block Copolymer Self-Assembly

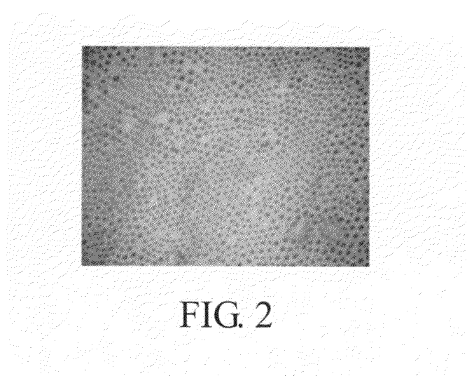

0.003 g PLA-b-P3HT-b-PLA was added to 1 mL chloroform and ultrasonically shaken for 60 min until the polymer was completely dissolved. Next, the solvent was removed by solvent casting. After vacuum baking at 80° C. for 12 hours, the block copolymer self-assembly was completed. The self-assembling polymer structure was photographed by a polarized optical microscopy (POM), as shown in FIG. 2.

### EXAMPLE 7

### Block Copolymer Self-Assembly

0.003 g PLA-b-P3HT-PLA was added to 1 mL chloroform and ultrasonically shaken for 60 min until the polymer was completely dissolved. Next, the solvent was removed by spin coating (2000 rpm, 30 sec). After vacuum baking at 80° C. for 12 hours, the block copolymer self-assembly was completed.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An active layer utilized in a solar cell, comprising:
a polymer film having a plurality of hollow column array structures formed therein; and
a semiconductor material filled in the hollow column structures.

2. The active layer utilized in a solar cell as claimed in claim 1, wherein the hollow column structure is perpendicular to the polymer film surface.

3. The active layer utilized in a solar cell as claimed in claim 1, wherein the hollow column structure has a diameter of 1˜100 nm.

4. The active layer utilized in a solar cell as claimed in claim 1, wherein the polymer film comprises conducting polymers.

5. The active layer utilized in a solar cell as claimed in claim 4, wherein the conducting polymer comprises poly(3-alkylthiophene), poly(p-phenylenevinylene), or polyfluorene.

6. The active layer utilized in a solar cell as claimed in claim 5, wherein the poly(3-alkylthiophene) comprises poly(3-hexylthiophene) (P3HT).

7. The active layer utilized in a solar cell as claimed in claim 1, wherein the semiconductor material has a weight ratio of 40˜80%.

8. The active layer utilized in a solar cell as claimed in claim 1, wherein the semiconductor material is N-type.

9. The active layer utilized in a solar cell as claimed in claim 8, wherein the N-type semiconductor material comprises light-absorbing semiconductor materials, carbonaceous materials, or combinations thereof.

10. The active layer utilized in a solar cell as claimed in claim 9, wherein the light-absorbing semiconductor material comprises CdS, CdSe, or CdTe.

11. The active layer utilized in a solar cell as claimed in claim 9, wherein the carbonaceous material comprises carbon 60 or 70 derivatives.

12. The active layer utilized in a solar cell as claimed in claim 11, wherein the carbon 60 derivative comprises [6,6]-Phenyl-C₆₁ butyric acid methyl ester (PC₆₁MB).

13. The active layer utilized in a solar cell as claimed in claim 11, wherein the carbon 70 derivative comprises [6,6]-Phenyl-C₇₁ butyric acid methyl ester (PC₇₁MB).

14. A method of fabricating an active layer utilized in a solar cell, comprising:
self-assembling a plurality of block copolymers to form a polymer film on a substrate;
removing a portion of the block copolymers to expose a plurality of hollow column array structures; and
filling a semiconductor material in the hollow column structures.

15. The method of fabricating an active layer utilized in a solar cell as claimed in claim 14, wherein the block copolymer comprises conducting polymers.

16. The method of fabricating an active layer utilized in a solar cell as claimed in claim 14, wherein the block copolymers have a polydispersity index (PDI) less than 1.6.

17. The method of fabricating an active layer utilized in a solar cell as claimed in claim 14, wherein the block copolymer comprises a first copolymer and a second copolymer.

18. The method of fabricating an active layer utilized in a solar cell as claimed in claim 17, wherein the first copolymer and the second copolymer are immiscible.

19. The method of fabricating an active layer utilized in a solar cell as claimed in claim 17, wherein the first copolymer comprises L-polylactic acid, meso-polylactic acid, polylactic acid, or polycaprolactone.

20. The method of fabricating an active layer utilized in a solar cell as claimed in claim 17, wherein the second copolymer comprises poly(3-alkylthiophene), poly(p-phenylenevinylene), or polyfluorene.

21. The method of fabricating an active layer utilized in a solar cell as claimed in claim 14, wherein the polymer film is formed on the substrate by spin coating.

22. The method of fabricating an active layer utilized in a solar cell as claimed in claim 14, wherein the substrate comprises a slide, carbon-coated slide, Indium Tin Oxide (ITO) glass, silicon wafer, silicon oxide, inorganic light emitting diode, or alumina.

23. The method of fabricating an active layer utilized in a solar cell as claimed in claim 17, wherein the first copolymers are removed by hydrolysis.
